(19) United States
(12) Patent Application Publication
(10) Pub. No.: US 2006/0103404 A1
(43) Pub. Date: May 18, 2006

(54) System and method for testing dynamic resistance during thermal shock cycling

(75) Inventors: Nitin B. Desai, Coral Springs, FL (US); Paul R. Crandall, North Lauderdale, FL (US); Ilya Lisak, Plantation, FL (US); Robert J. Mulligan, Coral Springs, FL (US); James L. Tracy, Coral Springs, FL (US); James A. Zollo, Weston, FL (US)

Correspondence Address: FLEIT, KAIN, GIBBONS, GUTMAN, BONGINI;& BIANCO P.L., 551 N.W. 77TH STREET, SUITE 111, BOCA RATON, FL, 33487, US

(73) Assignee: MOTOROLA, INC., SCHAUMBURG, IL (US)

(21) Appl. No.: 10/989,888

(22) Filed: Nov. 12, 2004

(51) Int. Cl. G01R 31/02

(52) U.S. Cl. 324/760

(57) ABSTRACT

A system includes a temperature chamber (100), a text fixture (402), a test coupon (400), a data acquisition unit (404), an ohmmeter (406) and a computer (410). The temperature chamber (100) provides temperature extremes to the test coupon (400). The test coupon (400) includes a substrate (314), one or more vias (418-429) and traces (402-412) connecting the vias. The data acquisition unit (404) continuously measures a resistance value of the circuit formed by the vias (418-429) and traces (402-412) during temperature cycling of the test coupon (400) held by the test fixture (402). The ohmmeter (406) measures the temperature of the test coupon (400) with a thermocouple. The data is used to detect failures of the materials in the test coupon (400) during the temperature cycling.

### FIELD OF THE INVENTION

The present invention generally relates to the field of thermal shock testing, and more particularly relates to continuous fault detection during thermal shock cycling.

### BACKGROUND OF THE INVENTION

The benchmark of product quality is reliability. Manufacturers of the most reliable products in a particular field are usually the most likely to succeed in the marketplace. For this reason, manufacturers spend vast amounts of time and money finding and eliminating failures from products before beginning the mass-production stage. This process of eliminating failures involves careful design and testing of each component in a product, with the type of test performed varying with the particular component and the intended use of the product.

For electronic circuit boards with plated-through holes, microvias, solder joints, battery contacts, embedded passive components, micro-ball-grid arrays, and other similar structures, a long-accepted method of reliability testing is exposing the board to a series of thermal shocks, which includes rapidly moving the board between environments of extreme heat and cold. The transition time between the two extremes is usually less than a few minutes, thus providing the “shock.”

As is well known, materials tend to contract or expand as the temperature of the material changes. The greater the value of the temperature differential, the greater the value of the expansion and contraction of the material. Because the rate and maximum variation of material expansion or contraction is not uniform in all materials, the changes in temperature can cause a first material to expand and separate from a second material that has a lower expansion delta or slower expansion rate. This phenomenon is exposed by providing extreme temperature limits within a short period of time.

Thermal shock testing is usually performed with a dual-chamber air-to-air or a liquid-to-liquid system. An air-to-air system is a device with two chambers, each providing an environment with a temperature extreme opposite to the other chamber. The device under test (DUT) is physically and quickly moved from one chamber to the next.

A liquid-to-liquid system is a two-chambered device containing special liquids. Each chamber providing a liquid that is at an opposite temperature extreme from the other chamber. A mechanism moves the DUT from one chamber to the other and the liquid provides a much faster temperature change than does the air-to-air chamber.

A third method of thermally shocking components is performed with hot sand. A component is removed from a cold chamber and immediately placed within a container of heated sand. The sand, much like liquid, immediately contacts all surface portions of the component, thus transferring high levels of heat into the component.

A disadvantage of thermal shock tests is that the DUT is contained within the chamber which contains temperatures unsafe for human presence, making it difficult to observe the onset of failures (e.g., cracks) and detect location of failures during any cycle of the test. The DUT can be tested thoroughly after the temperature cycling is completed, however, the measurements can be deceiving. As explained above, two differing materials will expand at different rates. At a temperature extreme, the board material may cause a fracture, warping, or other type of discontinuity to form in a conductive runner or trace on the board or circuit substrate. However, as the temperature returns to ambient, the materials return to their original dimensions and the trace may again provide a continuous electrical path. A test at ambient will not, in this case, detect the failure that occurs at the higher temperature.

In addition, many testing techniques utilize manual probing of the circuit with the testing leads. The pressure exerted by the leads making electrical contact with the board can cause the separated spaces between components and the board or within traces on the board, and the like, to close, thereby giving the false appearance of a functional board.

Another test for finding failures of circuit boards is called an Interconnect Stress Test (IST). In an IST, high current levels are passed through the traces on the circuit board so that the traces act as heating elements. The test is performed at ambient temperature. The IST suffers from several disadvantages. The test is unable to maintain consistent stress conditions throughout a DUT and from sample to sample. Additionally, IST boards are stressed internally in an ambient condition and because the test does not include the cold portion of the shock test, cannot be correlated to field conditions.

During any of the above-mentioned testing techniques, an additional factor can be added by physically twisting or flexing the board. Similar to the other tests, failures must be determined at the limits of the testing procedure, as the DUT may give the appearance of working properly once the flexing pressure is removed and the DUT returns to its static state.

Therefore a need exists to overcome the problems with the prior art as discussed above.

### SUMMARY OF THE INVENTION

Briefly, in accordance with the present invention, disclosed is an innovative test method and system that addresses the shortcomings of the conventional test methods. Unlike traditional failure detection methods, when used with thermal environmental chambers, the present invention facilitates a fast, accurate, real time continuous test. An embodiment of the present invention continually measures and compares changes in resistance of the conductive structures during actual temperature cycling tests. In this way, true reliability data is gained.

The present invention is comprised of high-resolution data acquisition hardware that is harnessed to specialized test vehicles (“coupons”) developed for the test. The device includes a test fixture, which facilitates connection of a 4-wire interconnect, and/or a 2-wire interconnect, to the coupons. A nano volt/micro ohm meter continuously measures the resistance while the temperature at the coupon alternates from hot to cold and cold to hot. From the test fixture, a 4-wire interface cable connects to a data acquisition unit, which makes a 4-wire milliohm measurement. With this acquisition unit, multiple test vehicles can be tested simultaneously.

A computer controls and retrieves data from the acquisition unit and software identifies pass/fail criteria, taking into account a calculated average of the coupon during the 3^{rd}, 4^{th}, and 5^{th} initial thermal cycling. At any time during the testing the 4-wire interconnect system can validate itself utilizing a checking method through two-wire interconnection and four-wire interconnection to assure coupon compliance.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a diagram illustrating one embodiment of a thermal chamber testing device according to an embodiment of the present invention.

FIG. 2 is a diagram illustrating a second embodiment of a thermal chamber testing device according to an embodiment of the present invention.

FIG. 3 is a block diagram illustrating one embodiment of a test coupon according to an embodiment of the present invention.

FIG. 4 is an overall system diagram illustrating one embodiment of a system for testing a device during thermal shock cycling according to an embodiment of the present invention.

FIG. 5 is a block diagram illustrating a second embodiment of a test coupon according to an embodiment of the present invention.

FIG. 6 is a block diagram illustrating a third embodiment of a test coupon according to an embodiment of the present invention.

FIG. 7 is a flow diagram of a process for performing reliability testing on a test coupon according to an embodiment of the present invention.

### DETAILED DESCRIPTION

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an”, as used herein, are defined as one or more than one. The term plurality, as used herein, is defined as two or more than two. The term another, as used herein, is defined as at least a second or more. The terms including and/or having, as used herein, are defined as comprising (i.e., open language). The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

The present invention, according to an embodiment, overcomes problems with the prior art by providing real-time continuous testing of a device undergoing thermal shock testing, while the device is at limits of the thermal test.

Described now is an exemplary hardware platform according to an exemplary embodiment of the present invention. Referring to FIG. 1, a temperature chamber 100 is shown. The particular temperature chamber shown is a two-chambered air-to-air device that has two separate doors 102 and 104 that allow access to two separate thermal chambers 106 and 108 and close to provide a sealed environment. In a preferred embodiment, the chambers 106 and 108 provide temperature extremes opposite from each other.

The device under test (DUT) (not shown) can be placed on a shelf 110 in chamber 106 or shelf 112 in chamber 108. Shelves 110 and 112 support the DUT and are perforated to allow air to flow from above and under the DUT and apply extreme heat or cold to the subject DUT. Temperatures within the chamber can range, for example, from −65 C to +130 C. Other exemplary temperature ranges may include from −55 C to +125 C and from −45 C to +130 C. The temperature range, or temperature ranges, for thermal shock testing a DUT can be selected for particular applications and/or for meeting certain industry standards, as will be obvious to those of ordinary skill in the art in view of the present discussion. To thermally shock a DUT, the DUT is rapidly moved from one environment to the next, with the limits of the thermal testing being a predetermined amount of time appropriate for the DUT. The movement of the DUT from one chamber to the other can be manual, or automatically achieved by mechanical means, or not necessary, as will be explained in more detail in the following paragraphs.

A typical chamber is programmable via a user interface 114 or controlled by a computer 116. In this way, the limits of the thermal testing and the period from a first temperature point to a second temperature point over a varying temperature pattern can be regulated.

Test chamber 100 is one embodiment of a temperature test chamber but the test chamber can have many other forms. For instance, in one embodiment, the test chamber 100 is a single-chamber test chamber providing both extreme heat and extreme cold to perform the thermal shock test with the advantage of not needing to move the DUT between extremes.

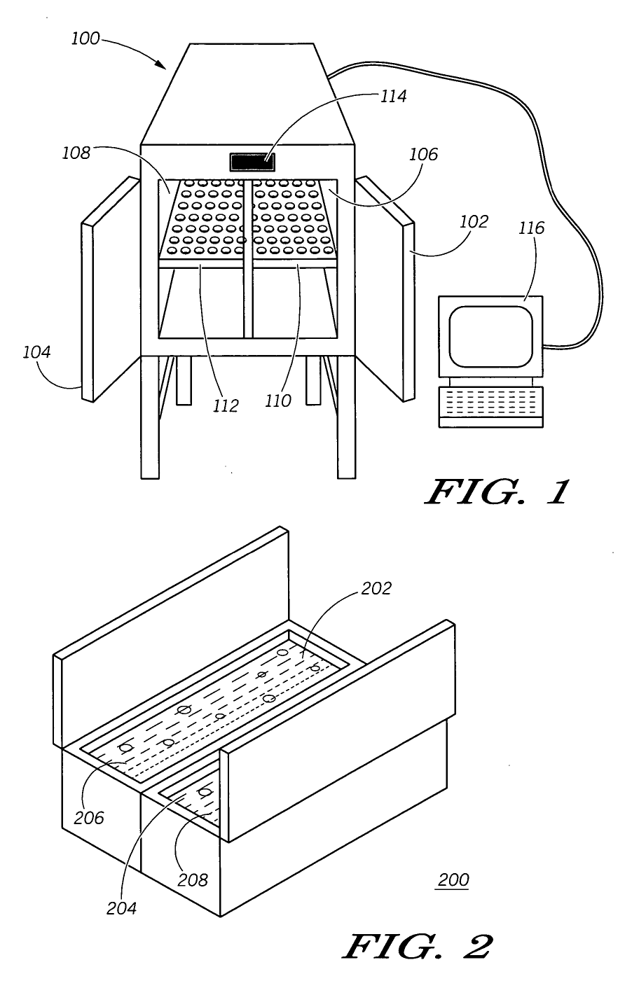

In another embodiment, the temperature chamber 200, as shown in FIG. 2, is a liquid-to-liquid chamber where the medium for affecting the temperature of the DUT (not shown) is a liquid material. The temperature chamber 200 shown in FIG. 2 includes two tanks 202 and 204 each containing a liquid material 206 and 208, respectively. The liquid materials 206 and 208 are maintained at opposite temperature extremes from each other.

The DUT is placed in one of the liquids 206 or 208 for a desired amount of time. The DUT is then rapidly transferred to the adjacent tank, thereby providing a temperature shock. Because of the direct physical contact of the liquid to the DUT, the liquid-to-liquid chambers have proven to provide a more rapid change between temperature extremes. As an alternative to the liquid, hot sand can also be used to provide a temperature shock.

Note also that temperature shock testing can optionally be applied to a DUT over a plurality of varying temperature patterns over time. A system, according to this alternative exemplary embodiment of the invention, can monitor a pass/fail criteria of the DUT based on a function of at least one electrical continuity measurement of at least one circuit of the DUT, taken at one temperature point, or alternatively at at least two temperature points, in one of the plurality of varying temperature patterns. For example, a first of the plurality of varying temperature patterns can be selected to be approximately −55 degrees centigrade and +125 degrees centigrade, and a second of the plurality of varying temperature patterns can be selected to be approximately 45 degrees centigrade and +130 degrees centigrade. Temperature shock testing of a DUT, in one example, could be monitored in a first varying temperature pattern at −55 degrees centigrade and +125 degrees centigrade, and alternatively could be monitored in a second varying temperature pattern at −45 degrees centigrade and +130 degrees centigrade. The switching between the two varying temperature patterns can be manual or automatic. Electrical continuity measurement of at least one circuit of the DUT can be taken, for example, at any one temperature point, or optionally at two or more temperature points, defined by the maximum high and minimum low temperature points of any of the plurality of varying temperature patterns. Therefore, a DUT could be automatically thermal shock tested over different temperature ranges during a single test protocol. This can significantly enhance the efficiency of thermal shock testing of a DUT while applying different temperature ranges such as may be desired to verify compliance with different application requirements and/or different industry standards.

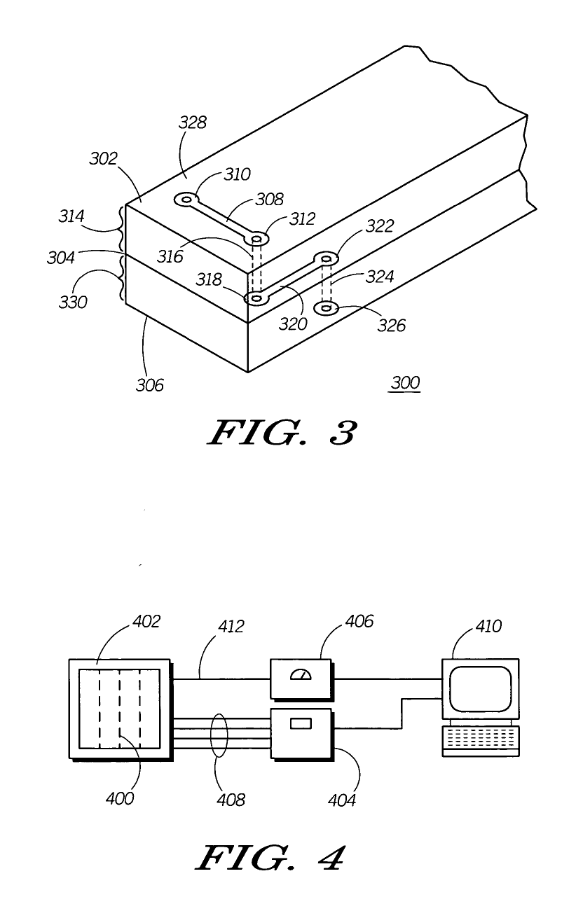

FIG. 3 shows an exemplary embodiment of a DUT 300. Due to the emphasis on reduction of size of electronic products, the available amount of surface area on the PCB (referred to as PCB “real estate”) allotted to components is ever shrinking. One method of placing more electronics on a given area is multilayered circuit boards or circuit supporting substrates. The coupon 300, shown in FIG. 3, is a multi-layered circuit board having a first 302, a second 304, and third 306 layer. The dimensions are overly exaggerated for illustrative purposes. Additionally, the DUT can have any number of layers other than 3.

Each layer includes electrically conductive pathways disposed on a non-conducting substrate material. The electrically conductive pathways run from one layer to the next. Looking to FIG. 3, an electrically conductive pathway, or “trace” 308, preferably made of copper, is shown attached to the upper surface of the multi-layered board 300. The trace is defined at its ends by two contact pads 310 and 312 and allows pad 310 to be electrically connected to pad 312. The trace 308 and the contact pads 310 and 312 are supported by and attached to substrate material 314. Contact pads 310 and 312 are utilized to physically contain the end flanges of the tube-shaped conductor 316 extending between layers, known as a “via.”

Vias, which are electrically conductive pathways from one layer to another, allow components on a first layer to participate in a circuit arrangement with components on a second or other layers. Via 316, shown as dashed lines, is a path of electrically conductive material connecting contact pad 312 on the first layer 302 to a contact pad 318 on the second layer 304, which is sandwiched between the first 314 and second substrate layer 330. A trace 320 connects contact pad 318 to contact pad 322, which is in turn connected to pad 326 on the third conductor layer 306 by a via 324. In this above described arrangement, a component on an upper surface 302 of the coupon 300 can be electrically connected to a component on a bottom surface 306 of the coupon 300. The arrangement avoids the space-consuming problem of having to place all components in a circuit on a single side of the board.

Once a product is placed in the marketplace, a manufacturer has no way of knowing what environments the product may be exposed to. For this reason, the reliability of a particular product is dependent on its ability to withstand exposure to extreme conditions, such extreme heat or cold, which may be found in nature or artificial environments.

As with almost all materials, a multi-layered board, such as the coupon 300, shown in FIG. 3, will expand or contract to at least some degree when exposed to extremely high or extremely low temperatures. If the expansion or contraction is too great, the substrate material may separate from the pad, trace, and via material or cause the pad trace, and via material to tear, thereby opening the circuit. As an example, if the substrate material 314 or 330 were to expand as a result of exposure to extreme heat, the contact pads 312 and 318 would be pushed in opposite directions. Similarly, contact pads 326 and 322 would be pushed in opposite directions. In this situation, if the copper, or any other material that vias 316 and 324 are constructed of does not expand by a similar amount, then a break, or “open”, in the circuit will occur.

It is therefore desirable to fully test a circuit board's reaction to extreme conditions to determine reliability before placing the product in the marketplace. It is also necessary to test the circuits at the extreme temperature limits and before the materials can return to their previous dimensions, as any separations in the pathways may close themselves as they return to an ambient temperature.

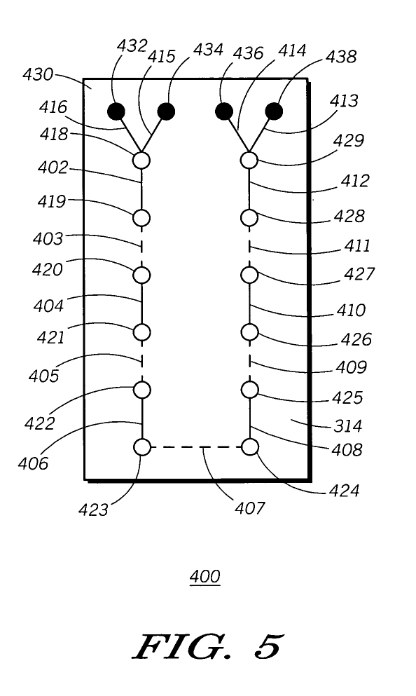

FIG. 4 shows a system for continuously testing a DUT 300 within a temperature chamber 100. The DUT 300 in the present invention is a test coupon 400. The test coupon 400 is shown in detail in FIG. 5 and will be explained in the proceeding paragraphs. Referring still to FIG. 4, the coupon 400 is placed within a test fixture 402 that is able to accommodate multiple coupons. From the test fixture 402, a 4-wire interface cable 408 connects to a data acquisition unit 404, such as a Hewlett Packard 34970A. The data acquisition unit 404 can make continuous 4-wire milliohm measurements of the coupon 400 in the test fixture 402. Four wires 408 are utilized to provide differential noise interference elimination, as is well known in the art. Noise is produced by many sources, such as 60 Hz noise broadcast from nearby power lines, emissions from other equipment in the vicinity, and the like. The noise reduction is realized by attaching dual leads to both the input and output of the circuit. Each lead remains in close proximity to its mate and is connected to the data acquisition unit 404. At the data acquisition unit 404, the noise signals on each set of leads are subtracted from each other, leaving only the test signal. Alternatively, two-wires out of the four-wires can be selected to make milliohm measurements of the coupon 400 in the test fixture 402. These two wires can be selected to make separate two-wire measurements of the coupon at any time during the testing so that the 4-wire interconnect system can validate itself utilizing a checking method through the two-wire interconnection and the four-wire interconnection to assure coupon interconnection compliance at all interconnections. It should be obvious to those of ordinary skill in the art in view of the present discussion that testing of the 4-wire interconnect, and of any two-wires of the four-wire interconnect, can include any combination of measurements of capacitance, inductance, resistance, and impedance measurement. By testing two-wire interconnection and four-wire interconnection at any time during a testing protocol, a test system can significantly increase testing reliability and testing flexibility.

A computer 410 is attached to the data acquisition unit 404 and controls and retrieves data from the unit 404, in a way that is well known in the art. Also attached to the test fixture 402 is a nanovolt/microohm meter thermocouple measuring probe 406, such as a Hewlett Packard 34420A, that measures the temperature at the coupon 400 as the coupon goes from hot to cold and cold to hot. The meter 406 is attached to the test fixture 402 or coupon 400 with a cable 412 and the computer 410 retrieves temperature information from the meter 406.

The test fixture 402, along with at least one coupon 400, is then placed within the temperature chamber 100 or 200 with the cables 408 and 412 running from within the chamber 100 outside to the meters 404 and 406. The test fixture 402, along with the test coupon 400 are sequentially brought from a maximum high temperature to a maximum low temperature, back to a maximum high, and so on. The data acquisition unit 404 and ohmmeter 406 continuously record data, such as resistance values, voltages, currents, impedance, capacitance, and other electrical measurements at each maximum high temperature, each maximum low temperature, and each ambient temperature. An on-going log is maintained within the computer that plots these (multiple) measured values over time.

Referring now to FIG. 5, a coupon 400 is shown in detail. A coupon 400 is a printed circuit board of the same material and manufacturing process of the circuit board design for which reliability is being determined. The coupon 400 is designed in such a way that at least one path of traces and vias are connected to form a closed circuit. FIG. 5 shows a coupon 400, which includes a substrate material 314 supporting copper traces 402-412 and vias 418-429. Each via 418-429 is an electrically conductive metallic material that passes from a first layer of the coupon 400 to at least a second layer and places the layers in electrical communication with one another. The coupon 400 shown in FIG. 5 is illustrated in a top view. Even numbered traces 402-412 are located on the top layer 430 and electrically connect via 418 to 419, 420 to 421, 422 to 423, 424 to 425, 426 to 427, and 428 to 429. Dashed lines represent traces that are arranged on layers other than the top layer 430 and are labeled as odd number 403-411. The odd number traces 403-411 connect via 419 to 420, 421 to 422, 423 to 424, 425 to 426, and 427 to 428, but are not necessarily on the same layers with each other. In the arrangement just described, a closed circuit is formed from via 418 to via 429.

If the short circuit is measured for a resistance value prior to the coupon 400 being subjected to temperature testing, a change in the physical structure of the circuit, such as breaking, tearing, or stretching of the traces and vias will be detected by continuously monitoring the resistance value of the circuit during temperature testing. Continuous measurement of values other than resistance, such as impedance, inductance, capacitance, and other measurements that should be obvious to those of ordinary skill in the art in view of the present discussion, can also indicate physical changes to the coupon 400.

A set of four test contacts 432, 434, 436, and 438 are provided on the top layer 430 of the coupon 400. When the coupon 400 is placed in the test fixture 402, each contact 432, 434, 436, and 438 is connected to one of the 4 wires of the 4-wire interface cable 408. The contacts 432 and 434 are connected to via 418 with traces 416 and 415, respectively, and the contacts 436 and 438 are connected to via 429 through traces 414 and 413, respectively.

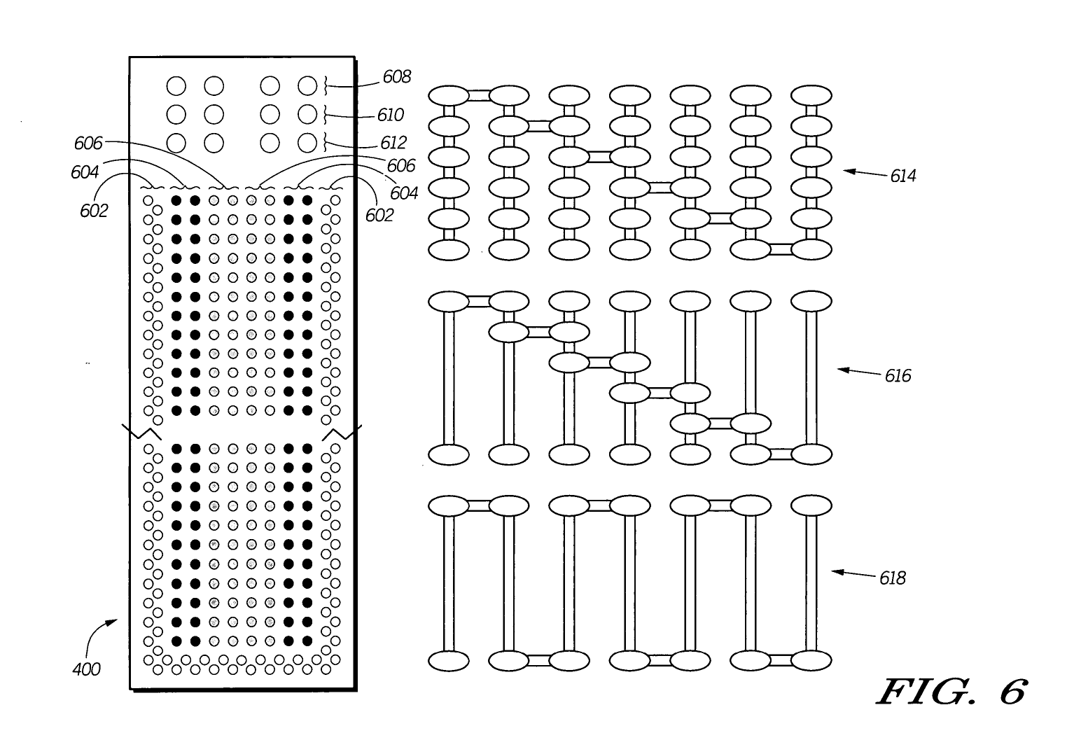

In a preferred embodiment, multiple circuits will be placed on each coupon 400. FIG. 6 shows a coupon 400 with three circuits 602, 604, and 606. Three 4-contacts sets 608, 610, and 612 are shown on the coupon 400 and are provided to connect each of the circuits 602, 604, and 606 to a 4-wire interface cable 408. Shown to the right of the coupon 400 in FIG. 6 are three circuit configurations 614, 616, and 618, shown in the side view, representing circuits 602, 604, and 606, respectively. Each circuit configuration 614, 616, and 618 is realized on a six-layer circuit board. In a preferred embodiment, the circuits vary from one another in the dimensions of the vias, dimensions of the pads, and dimensions of the plated through holes. In another embodiment, circuit 602 includes laser-cut vias of 6 mils and pads of 12 mils; circuit 604 includes laser-cut vias of 5 mils and pad of 10 mils; and circuit 606 includes laser-cut vias of 4 mils with pads of 8 mils. Other circuit configurations and dimensions other than the three shown in FIG. 6 may be used to continuously test a coupon 400 equally as well.

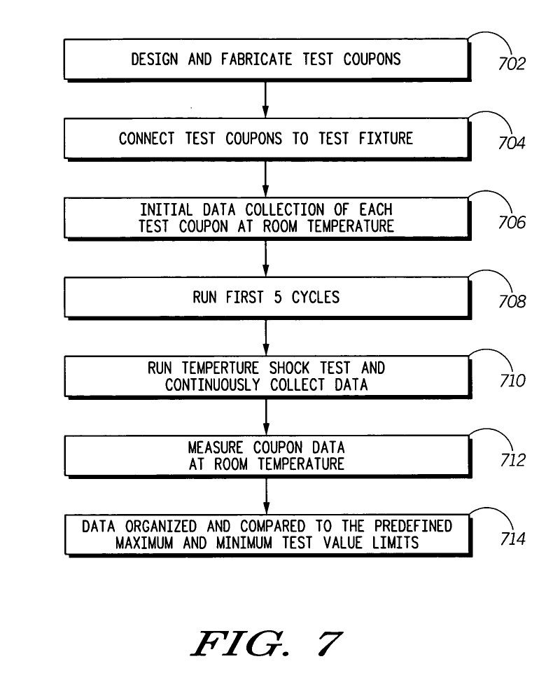

FIG. 7 shows a process flow chart of the present inventive test method. In a first step, 702, the test coupon 400 is designed and fabricated in accordance with the present invention. The coupon 400 is then connected to the 4-wire interface cable 408 via the test fixture 402, at step 704. An initial data collection of each coupon (DUT) 400 at room temperature (ambient) is then taken in step 706. A small pre-determined amount of temperature cycles ranging from maximum cold to maximum hot are then run on the coupon 400 in step 708, for determining a “bench-mark” or starting deference point. The purpose of step 708 is to set up the pass/fail criteria for each coupon 400.

The temperature shock testing begins in step 710, where temperature cycles run from maximum cold to maximum hot and data is continuously collected for each coupon 400 under test. After the temperature testing is complete, the device is measured one final time at room temperature in step 712. The data obtained is then organized and compared to the predefined maximum and minimum test value limits at step 714.

In the manner just described, the present invention enables continuous real-time quality and reliability testing of any interconnect structure or solder joints during environmental stresses. Failures and their sources can be pinpointed during temperature variations, even when the device appears to be within specifications at an ambient temperature. The present invention also provides significant cost and cycle time advantages over the prior art.

The present invention can be realized in hardware, software, or a combination of hardware and software. A system according to a preferred embodiment of the present invention can be realized in a centralized fashion in one computer system, or in a distributed fashion where different elements are spread across several interconnected computer systems. Any kind of computer system—or other apparatus adapted for carrying out the methods described herein—is suited. A typical combination of hardware and software could be a general purpose computer system with a computer program that, when being loaded and executed, controls the computer system such that it carries out the methods described herein.

The present invention can also be embedded in a computer program product, which comprises all the features enabling the implementation of the methods described herein, and which—when loaded in a computer system—is able to carry out these methods. Computer program means or computer program in the present context mean any expression, in any language, code or notation, of a set of instructions intended to cause a system having an information processing capability to perform a particular function either directly or after either or both of the following a) conversion to another language, code or, notation; and b) reproduction in a different material form.

Each computer system may include, inter alia, one or more computers and at least a computer readable medium allowing a computer to read data, instructions, messages or message packets, and other computer readable information from the computer readable medium. The computer readable medium may include non-volatile memory, such as ROM, Flash memory, Disk drive memory, CD-ROM, and other permanent storage. Additionally, a computer medium may include, for example, volatile storage such as RAM, buffers, cache memory, and network circuits. Furthermore, the computer readable medium may comprise computer readable information in a transitory state medium such as a network link and/or a network interface, including a wired network or a wireless network, that allow a computer to read such computer readable information.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and all such applications, modifications, and embodiments within the scope of the present invention.

What is claimed is:

1. A method for testing temperature cycling of circuit supporting substrates, the method comprising:
providing an electrical signal through at least one circuit of a circuit supporting substrate;
applying to the circuit supporting substrate a varying temperature pattern over time, including a first temperature point and a second temperature point that is different from the first, and providing the electrical signal to the at least one circuit at the first temperature point and at the second temperature point; and
monitoring a pass/fail criteria of the circuit supporting substrate based on a function of at least one electrical measurement of the at least one circuit taken at an at least one temperature point in the temperature pattern.

2. The method according to claim 1, wherein the at least one temperature point comprises:
at least one of a high temperature point, a low temperature point, and an ambient temperature point, being selected for thermal shock testing of the circuit supporting substrate.

3. The method according to claim 1, wherein the at least one electrical measurement comprises:
at least one of a capacitance, an inductance, a resistance, and an impedance measurement.

4. The method according to claim 1, wherein the circuit supporting substrate comprises a plurality of circuit layers.

5. The method according to claim 4, wherein the at least one circuit of the circuit supporting substrate comprises at least one electrically conductive path extending from a first circuit layer to at least a second circuit layer of the circuit supporting substrate.

6. The method according to claim 5, wherein the at least one electrically conductive path extends from a first circuit layer to at least a second circuit layer that is internal in the circuit supporting substrate.

7. The method according to claim 1, wherein the at least one electrical measurement of the at least one circuit is a continuous measurement over time taken using a differential signal circuit arrangement.

8. The method according to claim 1, wherein the temperature pattern comprises at least one range of temperatures.

9. A method of testing a circuit supporting substrate during temperature cycling, the method comprising:
applying a plurality of varying temperature patterns over time to a circuit supporting substrate; and
monitoring a pass/fail criteria of the circuit supporting substrate based on a function of at least one electrical continuity measurement of at least one circuit of the circuit supporting substrate, taken at at least two temperature points in one of the plurality of varying temperature patterns.

10. The method of claim 9, wherein the at least two temperature points comprise:
at least one of a high temperature point, a low temperature point, and an ambient temperature point.

11. The method according to claim 10, wherein the at least two temperature points are selected for thermal shock testing of the circuit supporting substrate.

12. The method according to claim 9, wherein the at least one electrical continuity measurement comprises:
at least one of a capacitance, an inductance, a resistance, and an impedance measurement.

13. The method according to claim 9, wherein the at least one circuit comprises two electrically conductive paths extending from a first circuit layer to at least a second circuit layer that is internal in the circuit supporting substrate, and wherein the monitoring of a pass/fail criteria of the circuit supporting substrate is based on a function of at least one electrical continuity measurement of the two electrically conductive paths of the circuit supporting substrate taken at at least two temperature points in one of the plurality of varying temperature patterns.

14. The method according to claim 9, wherein the at least two temperature points
in a first of the plurality of varying temperature patterns are selected to be approximately −55 degrees centigrade and +125 degrees centigrade, and
in a second of the plurality of varying temperature patterns are selected to be approximately −45 degrees centigrade and +130 degrees centigrade.

15. A system for testing a circuit supporting substrate during temperature cycling, the system comprising:
a first temperature medium for applying a first temperature point to a circuit supporting substrate, the circuit supporting substrate including at least one circuit;
a second temperature medium for applying a second temperature point to the circuit supporting substrate, the first temperature point and the second temperature point constituting a varying temperature pattern over time applied to the circuit supporting substrate;
an electrical signal generator for applying an electrical signal to the at least one circuit of the circuit supporting substrate at the first temperature point and the second temperature point in the varying temperature pattern; and
an electrical signal meter, for electrically coupling with the at least one circuit of the circuit supporting substrate, the electrical signal meter for measuring a pass/fail criteria of the circuit supporting substrate based on a function of at least one electrical continuity measurement taken of the at least one circuit of the circuit supporting substrate at an at least one temperature point in the varying temperature pattern.

16. The system of claim 15, wherein the first temperature medium and the second temperature medium are sequentially applied to the circuit supporting substrate in at least one temperature chamber.

17. The system of claim 15, wherein the first temperature medium comprises a first liquid bath and the second temperature medium comprises a second liquid bath, and wherein the first temperature medium and the second temperature medium are sequentially applied to the circuit supporting substrate by alternating the circuit supporting substrate between the first liquid bath and the second liquid bath.

18. The system of claim 15, wherein the electrical signal meter for contemporaneously electrically coupling with two circuits of the circuit supporting substrate for measuring a pass/fail criteria of the circuit supporting substrate based on a function of at least one electrical continuity measurement taken of the two circuits of the circuit supporting substrate at an at least one temperature point in the varying temperature pattern.

19. The system of claim 15, wherein the system for automatically
applying the first temperature point,
applying the second temperature point, and
taking the at least one electrical continuity measurement of at least two circuits of the circuit supporting substrate at the at least one temperature point in the varying temperature pattern.

20. The system of claim 15, wherein the electrical signal meter for continuously measuring over time at least one of a capacitance, an inductance, a resistance, and an impedance measurement of the at least one circuit of the circuit supporting substrate.
